(19) United States
(12) Patent Application Publication
(10) Pub. No.: US 2012/0241412 A1
(43) Pub. Date: Sep. 27, 2012

(54) PLASMA PROCESSING APPARATUS AND PLASMA PROCESSING METHOD

(75) Inventor: Takahiro MURAKAMI, Hwaseong-City (KR)

(73) Assignee: Tokyo Electron Limited, Tokyo (JP)

(21) Appl. No.: 13/428,624

(22) Filed: Mar. 23, 2012

Related U.S. Application Data
(60) Provisional application No. 61/477,181, filed on Apr. 20, 2011.

(30) Foreign Application Priority Data
Mar. 25, 2011 (JP) 2011-068370

(51) Int. Cl. B44C 1/22; H01L 21/3065; B05C 9/00

(52) U.S. Cl. 216/67; 156/345.24

(57) ABSTRACT

In a plasma processing apparatus for performing a plasma process on a substrate, a damage on a surface of a mounting table can be suppressed without using a dummy wafer when cleaning an inside of the plasma processing apparatus. Upon the completion of a plasma etching process, a surface of the susceptor 3 is exposed, and an inside of a vacuum chamber 1 of the plasma etching apparatus is cleaned by plasma P. Thus, reaction products A adhering to the inside of the vacuum chamber 1 are removed. Here, a DC voltage is applied to the plasma P during the cleaning process. As a result, while obtaining high-density plasma P, the ion energy can be reduced, so that the cleaning process can be performed effectively while suppressing damage on the surface of the susceptor 3.

### CROSS-REFERENCE TO RELATED APPLICATION

This application claims the benefit of Japanese Patent Application No. 2011-068370 filed on Mar. 25, 2011, and U.S. Provisional Application Ser. No. 61/477,181 filed on Apr. 20, 2011, the entire disclosures of which are incorporated herein by reference.

### FIELD OF THE INVENTION

The present disclosure relates to a technique for cleaning the inside of a vacuum chamber of a plasma processing apparatus by plasma.

### BACKGROUND OF THE INVENTION

In a plasma process performed on a surface of a semiconductor wafer in a semiconductor device manufacturing process, as the number of processes increases, the amount of reaction products adhering to an inner wall of a vacuum chamber or a mounting table also increases. If the adhesion amount increases, processing environment may be changed, resulting in deterioration of process uniformity between wafers. Furthermore, the increase of the adhesion amount may also cause particle generation. To solve these problems, by way of example, the inside of the vacuum chamber is regularly cleaned by plasma generated from a cleaning gas. For example, in an apparatus in which a plasma etching process is performed by plasma of a carbon fluoride (CF) gas, CF-based reaction by-products are ashed by using an oxygen (O₂) gas as the cleaning gas. In such a case, in order to prevent a surface of the mounting table from being damaged, the cleaning process by the plasma is typically performed after mounting a dummy wafer on the mounting table. In this method, however, since a process for loading and unloading the dummy water into and from the vacuum chamber is additionally required, throughput of the manufacturing process may be reduced, and manufacturing cost may be increased due to high cost of the dummy wafer. In order to reduce the manufacturing cost, a cleaning process may be performed without using the dummy wafer. In such a case, however, since the surface of the mounting table is exposed to the plasma, the surface of the mounting table may be roughened. If the degree of surface roughness of the mounting table increases, a heat transfer state between the mounting table and the wafer may be varied. As a result, a wafer processing temperature is deviated from a preset temperature. Accordingly, the frequency of replacement of an electrostatic chuck may be increased.

It is described in Patent Document 1 that DC powers are superposed in the plasma etching process. However, such superposition of the DC powers is not intended to be applied to a cleaning process for cleaning the inside of the plasma etching apparatus, which is different from a present disclosure to be described later. Meanwhile, although a cleaning process for cleaning a processing chamber is described in Patent Document 2, superposition of DC powers is not mentioned in this method.

Patent Document 1: Japanese Patent Laid-open Publication No. 2007-180358
Patent Document 2: Japanese Patent Laid-open Publication No. 2007-214512

### BRIEF SUMMARY OF THE INVENTION

In view of the foregoing problems, illustrative embodiments provide a technique capable of suppressing damage on a surface of a mounting table when a cleaning process is performed on a substrate of a plasma processing apparatus by plasma without using a dummy wafer.

In accordance with one aspect of an illustrative embodiment, there is provided a parallel plate type plasma processing apparatus for mounting a substrate on a mounting table serving as a first electrode in a vacuum chamber; generating plasma of a processing gas by applying a high frequency power between the first electrode and a second electrode; and performing a plasma process on the substrate by the plasma. The apparatus includes a DC voltage application electrode which is provided in a region exposed to the plasma; a DC power supply configured to apply a DC voltage to the DC voltage application electrode; a cleaning gas supply unit configured to supply a cleaning gas for cleaning an inside of the vacuum chamber; and a controller. The controller is configured to output a control signal so as to cause the plasma processing apparatus to perform a series of processes of supplying the cleaning gas into the vacuum chamber without mounting a substrate on the mounting table; exciting the cleaning gas into plasma by applying a high frequency power between the first electrode and the second electrode; and applying a DC voltage to the DC voltage application electrode while exiting the cleaning gas into the plasma.

In accordance with another aspect of an illustrative embodiment, there is provided a plasma processing method that includes mounting a substrate on a mounting table serving as a first electrode in a vacuum chamber, exciting plasma of a processing gas by applying a high frequency power between the first electrode and a second electrode, and performing a plasma process on the substrate by the plasma; supplying a cleaning gas into the vacuum chamber without mounting a substrate on the mounting table, and exciting the cleaning gas into plasma by applying a high frequency power between the first electrode and the second electrode; and applying, while exciting the cleaning gas into the plasma, a DC voltage to a DC voltage application electrode provided in a region exposed to the plasma.

In accordance with the illustrative embodiment, when removing reaction products adhering to the vacuum chamber of the plasma processing apparatus by plasma without mounting a substrate on the mounting table, by applying a DC power to the plasma, ion energy of the plasma can be decreased while maintaining high electron density of the plasma. Accordingly, a cleaning process for cleaning the vacuum chamber can be performed effectively. Further, since a sputtering action by the plasma is reduced, it is possible to suppress damage on the surface of the mounting table.

### BRIEF DESCRIPTION OF THE DRAWINGS

Non-limiting and non-exhaustive embodiments will be described in conjunction with the accompanying drawings. Understanding that these drawings depict only several embodiments in accordance with the disclosure and are, therefore, not to be intended to limit its scope, the disclosure will be described with specificity and detail through use of the accompanying drawings, in which:

FIG. 1 is a longitudinal side view of a plasma etching apparatus in accordance with an illustrative embodiment;

FIG. 2 is a block diagram illustrating a controller of the plasma etching apparatus;

FIG. 3 is a flowchart for describing an etching process and a cleaning process in accordance with the illustrative embodiment;

FIG. 4 is a schematic diagram for describing a cleaning process for removing deposits in accordance with the illustrative embodiment;

FIG. 5 is a schematic diagram for describing an operation in accordance with the illustrative embodiment;

FIG. 6 is a schematic diagram illustrating another illustrative embodiment;

FIG. 7 is a schematic diagram illustrating a surface shape of an electrostatic chuck in accordance with an experimental example;

FIG. 8 is a chart showing a test result of an experimental example;

FIG. 9 is a chart showing a test result of an experimental example;

FIG. 10 is a chart showing a test result of an experimental example;

FIG. 11 is a chart showing a test result of an experimental example; and

FIG. 12 is a chart showing a test result of an experimental example.

### DETAILED DESCRIPTION OF THE INVENTION

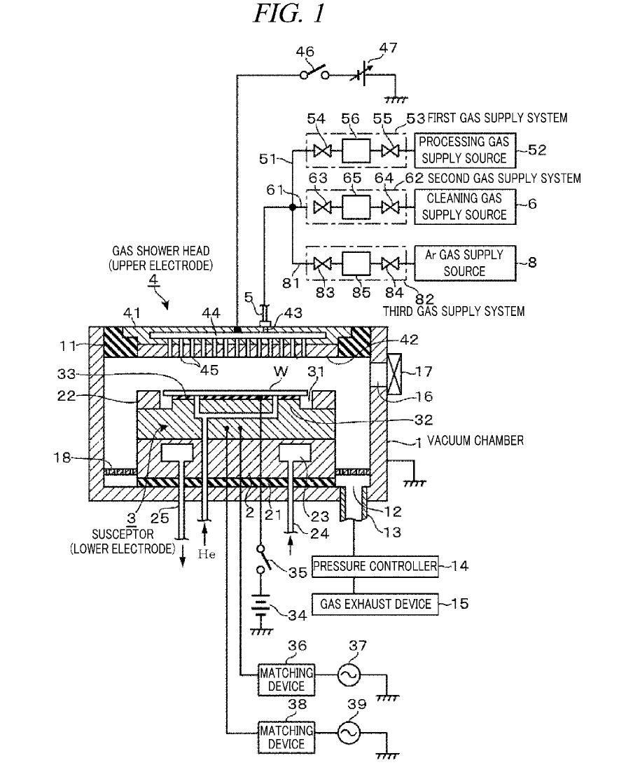

Hereinafter, a plasma etching apparatus in accordance with an illustrative embodiment will be described with reference to FIG. 1. The plasma etching apparatus is configured as a capacitively coupled parallel plate plasma etching apparatus.

A mounting table 2 is provided at the bottom of a vacuum chamber 1 via an insulating layer 21 made of, e.g., ceramic. A susceptor 3 made of, but not limited to, aluminum is provided on this mounting table 2. The susceptor 3 serves as a lower electrode. A step-shaped portion 31 is formed along the periphery of a top portion of the susceptor 3. An electrostatic chuck 33 configured to attract and hold a wafer W by an electrostatic force is provided on a protruding portion 32 at the central portion of the top of the susceptor 3. A chuck electrode is electrically connected with a DC power supply 34 via a switch 35. The susceptor 3 serving as the lower electrode is electrically connected with a first high frequency power supply 37 for plasma generation via a matching device 36. Further, the susceptor 3 is also electrically connected with a second high frequency power supply 39 for supplying a bias power for ion attraction via a matching device 38.

In order to improve etching uniformity, a ring member 22 referred to as a focus ring is provided on the step-shaped portion 31 of the susceptor 3 so as to surround the electrostatic chuck 33.

A coolant path 23 is formed within the mounting table 2, for example, along a circumferential direction of the mounting table 2. A coolant of a preset temperature, e.g., cooling water is supplied into and circulated through the coolant path 23 from a non-illustrated external chiller unit via pipelines 24 and 25. By adjusting the temperature of the coolant, a processing temperature for the wafer W can be controlled. Furthermore, a heat transfer gas such as a helium (He) gas is supplied from a non-illustrated heat transfer gas supply device to a space between a top surface of the electrostatic chuck 33 and a rear surface of the wafer W through a gas supply line.

An upper electrode 4 serving as a gas shower head is provided above the susceptor 3 serving as the lower electrode and is arranged to face the susceptor 3. A space between the upper electrode 4 and the lower electrode (susceptor) 3 is a plasma generation space. The upper electrode 4 includes a main body 41 and a ceiling plate 42 as an electrode plate, and is supported at a top portion of the vacuum chamber 1 via an insulating shield member 11. The main body 41 is made of a conductive material such as, but not limited to, aluminum having an anodiccally oxidized surface. The ceiling plate 42 is detachably supported at a bottom portion of the main body 41.

A gas diffusion space 44 communicating with a gas inlet 43 at a top portion of the main body 41 is formed within the main body 41. By way of example, a multiple number of gas discharge holes 45 are extended from the gas diffusion space 44 so as to be uniformly arranged. A processing gas supplied into the gas diffusion space 44 is uniformly diffused and supplied into a processing atmosphere through the gas discharge holes 45, as in a shower device.

A gas supply pipe 5 is connected to the gas inlet 43 at the top portion of the main body 41, and a base side of the gas supply pipe 5 is branched into first to third branch lines 51, 61 and 81. The first branch line 51 is connected with a processing gas supply source 52 via a first gas supply system 53. A gas containing a carbon atom C and a fluorine atom F as active ingredients, such as a CF-based gas, a CHF-based gas or a mixture of a CF-based gas and a CHF-based gas, may be used as a processing gas. By way of example, the CF-based gas may be, but not limited to, a C₄F₈ gas, a C₄F₆ gas or a C₅F₈ gas, and the CHF-based gas may be, but not limited to, a CHF₃ gas or a CH₂F₂ gas. The second branch line 61 is connected with a cleaning gas supply source 6 via a second gas supply system 62. By way of example, an oxygen (O₂) gas may be used as a cleaning gas, and polymer deposits within the vacuum chamber 1 are removed by ashing by plasma of the O₂ gas. The third branch line 81 is connected with an argon (Ar) gas supply source 8 via a third gas supply system 82. The Ar gas is used by being mixed with the cleaning gas to stabilize the plasma. The gas supply system 53 includes valves 54 and 55 and a flow rate controller 56. The gas supply system 62 includes valves 63 and 54 and a flow rate controller 65. The gas supply system 82 includes valves 83 and 84 and a flow rate controller 85. Furthermore, start or stop of the supply of the gases and flow rates of the gases are controlled in response to control signals from a controller 7 to be described later.

The upper electrode 4 is electrically connected with a variable DC power supply 47 via a switch 46, and power feed from the variable DC power supply 47 is turned on and off by the on/off switch 46. As will be described later, by applying a DC voltage of a certain magnitude to the upper electrode 4, ion energy of the plasma can be reduced without reducing an electron density of the plasma. Accordingly, even when a plasma cleaning process is performed without using a dummy wafer, the deposits within the vacuum chamber 1 can be ashed and removed while suppressing damage on the surface of the electrostatic chuck 33. The magnitude of the applied DC voltage may range from, e.g., about −200 V to about −320 V, more desirably, from, e.g., about −200 V to about −300 V.

A gas exhaust port 12 is formed at a bottom of the vacuum chamber 1, and a gas exhaust device 15 is connected to the gas exhaust port 12 through a gas exhaust pipe 13 via a pressure controller 14. With this configuration, the inside of the vacuum chamber 1 can be depressurized to a desired vacuum pressure. Furthermore, a loading/unloading port 16 for the wafer W is formed at a sidewall of the vacuum chamber 1. The loading/unloading port 16 can be opened and closed by a gate valve 17. Furthermore, a baffle plate 18 is provided between the sidewall of the vacuum chamber 1 and the mounting table 2 at a lower portion of the vacuum chamber 1.

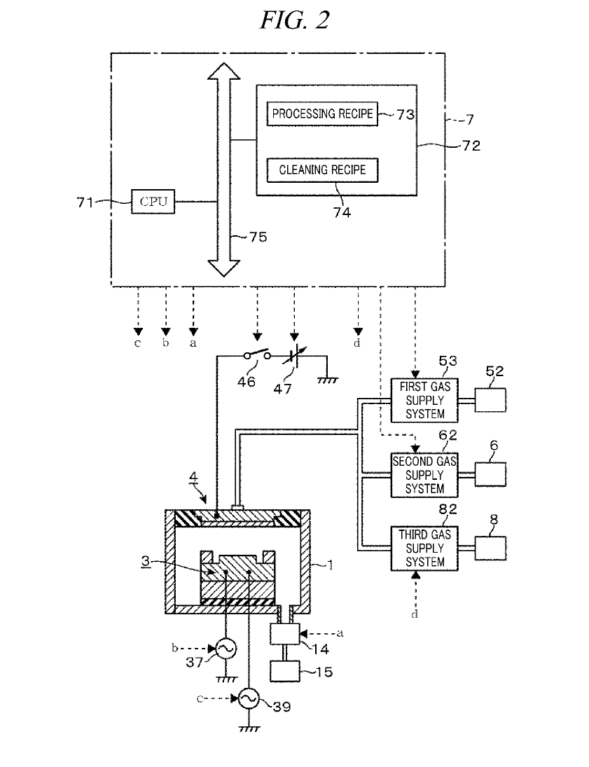

As mentioned, the plasma etching apparatus includes the controller 7. The controller 7 includes, as shown in FIG. 2, a CPU 71 and a recipe storage 72. In the recipe storage 72, a processing recipe 73 including, e.g., data of operation parameters of processing conditions in an etching process, or a cleaning recipe 74 including, e.g., data of operation parameters of processing conditions in a cleaning process is stored in a storage medium such as a CD-ROM or a DVD-R. The first high frequency power supply 37; the second high frequency power supply 39; the variable DC power supply 47; the on/off switch 46; the first gas supply system 53; the second gas supply system 62; and so forth are controlled by the controller 7 based on the processing recipe 73 and the cleaning recipe 74. A reference numeral 75 denotes a bus.

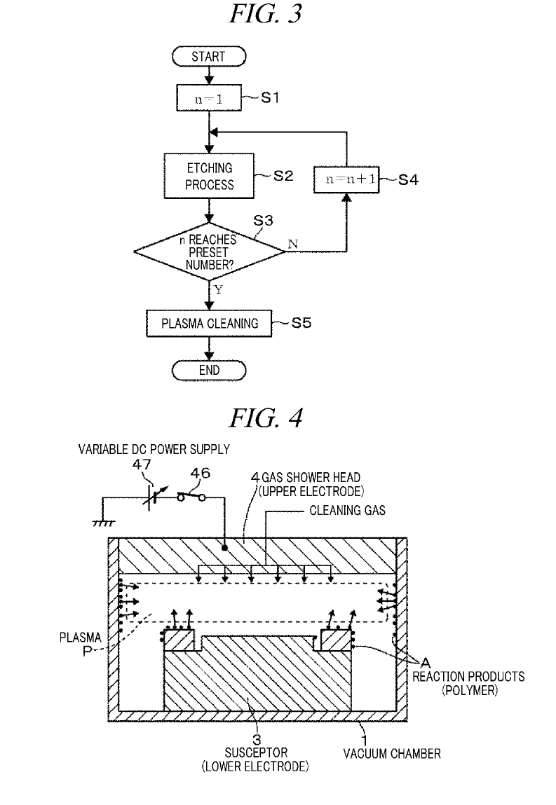

Now, an operation in accordance with the illustrative embodiment will be explained. Assume that an operation of the apparatus is started after cleaning the inside of the vacuum chamber 1. The controller 7 sets a processing number to ‘1’ (n=1) in step S1 of FIG. 3, and an etching process is started (step S2). First, the gate valve 17 is opened, and a wafer W as a target substrate to be etched is loaded into the vacuum chamber 1 through the loading/unloading port 16 by a non-illustrated transfer arm provided outside the vacuum chamber 1. Then, the wafer W is mounted on the susceptor 3 via a non-illustrated elevating pin, and attracted to and held on the electrostatic chuck 33. After the gate valve 17 is closed, a processing gas containing a compound gas of carbon and fluorine is supplied from the processing gas supply source 52 into the vacuum chamber 1 at a certain flow rate through the gas shower head (upper electrode) 4. An internal pressure of the vacuum chamber 1 is set to a vacuum atmosphere ranging from, e.g., about 0.1 Pa to about 150 Pa. A high frequency power for plasma generation is applied from the first high frequency power supply 37 to the susceptor 3 serving as the lower electrode at a certain power level. Further, a high frequency power for ion attraction is also applied to the susceptor 3 from the second high frequency power supply 39 at a preset power level. Accordingly, the processing gas is excited into plasma, and a processing target surface of the wafer W is etched by radicals or ions in the generated plasma. The etched wafer W is then unloaded from the vacuum chamber 1 in the reverse sequence as it is loaded. Thereafter, an etching process is performed on a subsequent wafer W (steps S3, S4 and S2). If the number of processed wafers W reaches a preset number, a cleaning process (step S5) for cleaning the inside of the vacuum chamber 1 is performed.

Upon beginning the cleaning process, as depicted in FIG. 4, a surface of the susceptor 3 is exposed to a plasma processing region. Furthermore, reaction products A generated during the etching process adhere to the vicinities of a wafer mounting area of the susceptor 3 such as the inner wall of the vacuum chamber 1 and the ring member 22. In accordance with the present illustrative embodiment, since the CF-based or CHF-based gas is used as the processing gas, reaction products A mainly made of polymer adhere to the inside of the vacuum chamber 1. With the wafer mounting area of the susceptor 3 exposed, i.e., without mounting a dummy wafer on the susceptor 3, the cleaning gas such as an O₂ gas is supplied into the vacuum chamber 1 from the cleaning gas supply source 6 at a preset flow rate of, e.g., about 700 sccm (standard cc/min.). Furthermore, an Ar gas is also supplied into the vacuum chamber 1 from the Ar gas supply source 8 at a preset flow rate of, e.g., about 700 sccm. Then, the internal pressure of the vacuum chamber 1 is set to, e.g., about 400 mTorr, and a high frequency power of, e.g., about 40 MHz for plasma generation is applied at a preset power level of, e.g., about 800 W. Then, a DC voltage ranging from, e.g., about −200 V to about −320 V is applied to the upper electrode 4 from the variable DC power supply 47. The cleaning gas (O₂ gas) is excited into plasma by the high frequency power, and the polymer A as deposits adhering to the inside of the vacuum chamber 1 are ashed by oxygen radicals or ions and removed from the vacuum chamber 1 to the outside. The cleaning process is performed for, e.g., about 1 minute.

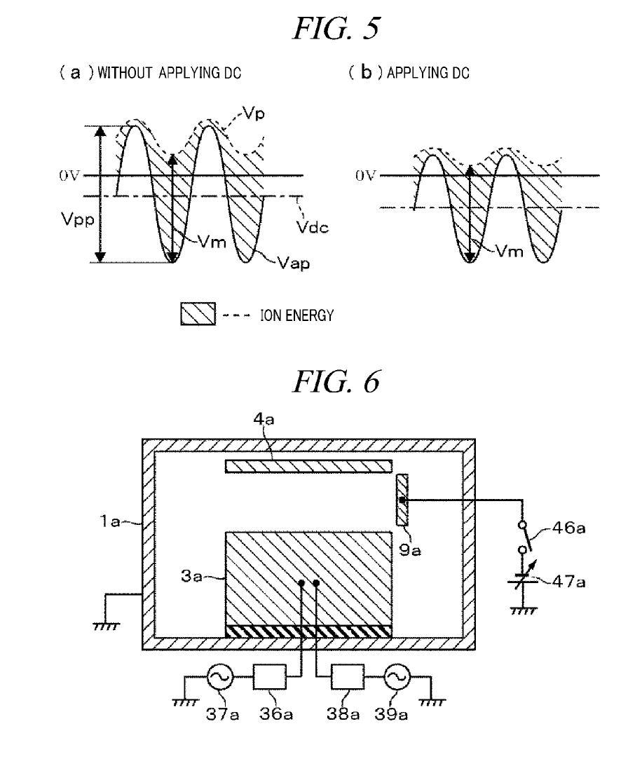

Here, a detailed operation during the plasma cleaning process and an effect of applying the DC voltage will be explained with reference to FIG. 5. In case that a DC voltage is not applied to the upper electrode, plasma having a plasma potential Vₚ is generated by applying a high frequency voltage Vₐₚ to the lower electrode, as illustrated in FIG. 5(a). A difference between the plasma potential Vₚ and the high frequency voltage Vₐₚ becomes ion energy in the plasma.

If a DC voltage is applied to the plasma by applying the DC voltage to the upper electrode 4, amplitude of the high frequency voltage Vₐₚ is decreased. Such a relationship is proved from a measurement result of a Vₚₚ (difference between an upper peak and a lower peak) of the high frequency voltage Vₐₚ in an experimental example to be described later. Furthermore, as a result of applying the DC voltage, a DC potential (V_{dc}) of the susceptor 3, the ring member 22 and the like is decreased (i.e., an absolute value of a negative voltage is increased). Since the plasma potential Vₚ also decreases with the descent of the amplitude of the high frequency voltage Vₐₚ, a maximum value Vₘ of the ion energy is decreased.

Meanwhile, the ion energy is deeply related with the intensity of physical sputtering action by argon ions or oxygen ions in the plasma. Especially, if the maximum value Vₘ of the ion energy, i.e., a value of the ion energy at a time point when the plasma potential Vₚ and the high frequency voltage Vₐₚ have minimum values, is increased, the sputtering action on the surface of the susceptor 3 increases. As a result, the surface roughness of the susceptor 3 is also increased. A processed state of the wafer W may depend on the surface roughness of the susceptor 3. In accordance with the illustrative embodiment, since the maximum value Vₘ of the ion energy is decreased by applying the DC voltage to the plasma, the inside of the vacuum chamber 1 can be cleaned while suppressing a variation of the surface roughness of the wafer mounting area of the susceptor 3. Here, it would be considered to reduce the power of the first high frequency power supply 37 as a way only to reduce the ion energy for plasma generation. In such a case, however, the degree of gas dissociation would also be decreased. As a result, plasma density (specifically, density of active species in the plasma) is reduced and it may not possible to perform an effective cleaning process. In contrast, in accordance with the cleaning process of the present illustrative embodiment, it is possible to suppress an excessive sputtering action by reducing the ion energy while obtaining sufficient plasma density.

In accordance with the aforementioned illustrative embodiment, upon the completion of the plasma etching process, the surface of the susceptor 3 is exposed, and the inside of the vacuum chamber 1 is cleaned by plasma P. Here, the DC voltage is applied to the plasma P during the cleaning process. Accordingly, while obtaining high-density plasma, the ion energy can be reduced, so that the cleaning process can be performed effectively while suppressing damage on the surface of the susceptor 3. As stated above, since heat conductivity between the susceptor 3 and the wafer W varies depending on the degree of surface roughness of the susceptor 3, process uniformity between wafers W may be deteriorated as the number of cleaning operations increases in the conventional wafer-less cleaning process. To solve this problem, regular maintenance including replacement of the electrostatic chuck 33 would be required. In accordance with the illustrative embodiment, however, the cycle of maintenance can be lengthened (frequency of maintenance can be decreased) because damage on the surface of the susceptor 3 can be suppressed. Although the wafer-less cleaning is advantageous in that no dummy wafer is used, the wafer-less cleaning is disadvantageous in that the surface of the susceptor 3 may be damaged. In this aspect, the illustrative embodiment is deemed to be an advantageous and useful technology.

In the above-described illustrative embodiment, although the DC voltage is applied to the upper electrode 4 serving as the gas shower head, the DC voltage may be applied to an electrode 9a positioned to face a lateral side of the plasma processing region, as depicted in FIG. 6. In FIG. 6, components having the same functions as those described in the above-described illustrative embodiment are assigned ‘a’ in addition to the reference numerals of the corresponding components, and redundant description thereof is omitted. Moreover, the above-described illustrative embodiment may also be applied to a case of applying a DC voltage to an upper electrode in a plasma processing apparatus applying dual frequencies to the upper and lower electrodes (i.e., a plasma processing apparatus that applies a high frequency power for plasma generation to the upper electrode and a high frequency bias power to the lower electrode). Furthermore, it may be also possible to apply a DC voltage to the ring member 22 called a focus ring for adjusting the plasma state in a plasma processing apparatus that applies dual frequencies to the lower electrode as in the above-described illustrative embodiment.

In the above-described illustrative embodiment, the O₂ gas is used as the cleaning gas. However, the cleaning gas may be appropriately selected in consideration of compositions of deposits to be removed. By way of example, when an O₂ gas is included as an etching gas for etching a polysilicon film, a fluorine gas may be used to remove silicon oxide-based deposits generated by the etching. The cleaning gas may be used by being mixed with, e.g., another kind of cleaning gas.

The above-described illustrative embodiment has been described for the case of performing the cleaning process after the plasma etching process. However, the illustrative embodiment is not limited thereto. By way of example, the illustrative embodiment may be applied to a case of removing a thin film adhering to a vacuum chamber by plasma of, e.g., a CF-based cleaning gas or a fluorine gas after a CVD (Chemical Vapor Deposition) process.

### EXPERIMENTAL EXAMPLES

Hereinafter, experiments in accordance with an illustrative embodiment will be explained.

(Experiment 1: Damage Test on Surface of Electrostatic Chuck)

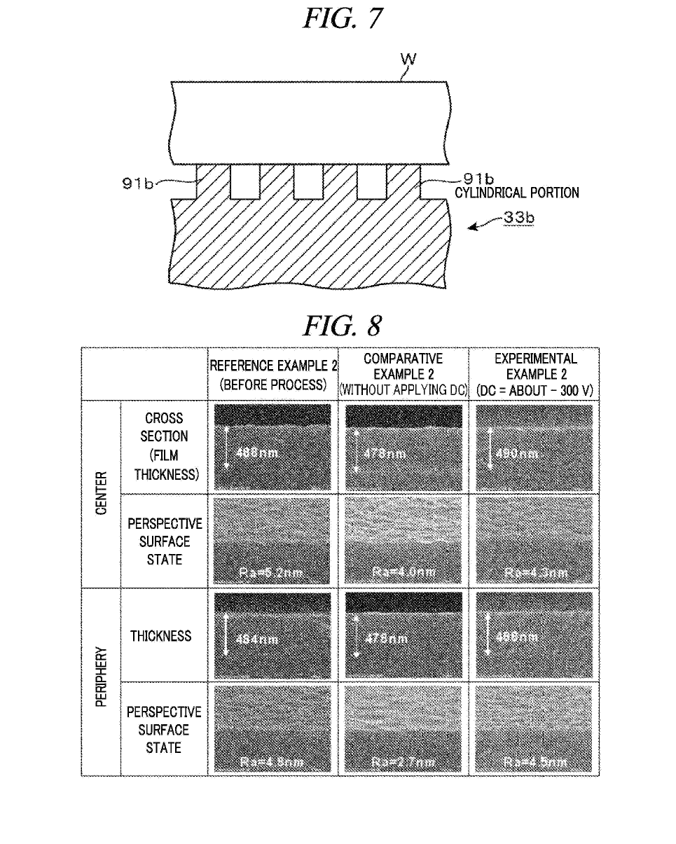

Referring to FIG. 7, a multiple number of minute cylindrical portions 91b are formed over the entire surface of an electrostatic chuck 33b. When a wafer W is mounted on the electrostatic chuck 33b, the wafer W comes into contact with flat top surfaces of the cylindrical portions 91b. It is very important that the shape of the cylindrical portions 91b does not change before and after performing a plasma cleaning process. If the plasma cleaning process is performed without using a dummy wafer, it is likely that the shape of the cylindrical portions 91b would be changed and, thus, their contact areas between the wafer W and the cylindrical portions 91b would be decreased. If the contact areas between the cylindrical portions 91b and the wafer W are decreased, a heat transfer between the wafer W and the susceptor would be changed. As a result, it would be difficult to control semiconductor devices to have the uniform quality. Here, under certain processing conditions, a plasma cleaning process is performed without using a dummy wafer while exposing the surface of the electrostatic chuck 33 to a processing region. Then, a variation in the shape of the cylindrical portions 91b is investigated depending on whether a DC voltage is applied or not. A sample before performing a plasma process is referred to as a reference example 1; a sample in case of performing a plasma process by applying a DC voltage is referred to as an experimental example 1; and a sample in case of performing a plasma process without applying a DC voltage is referred to as a comparative example 1. Processing conditions are as follows.

Pressure within vacuum chamber: about 53.3 Pa (about 400 mTorr)

First high frequency power: about 800 W

Kind and flow rate of cleaning gas: O₂ gas, about 700 sccm

Plasma processing time: about 50 hours

Applied DC voltage: about 0 V (comparative example 1), about −300 V (experimental example 1)

After performing the plasma process, degree of damage on top surfaces of cylindrical portions 91b is observed at a central portion and a periphery portion of a wafer W of each sample by a SEM (Scanning Electron Microscope), respectively. Furthermore, roughness of top surfaces of the cylindrical portions 91b (arithmetical mean roughness (Ra)) and diameter of the top surfaces of the cylindrical portions 91b at the central portion and the periphery portion of the wafer are also measured and compared with corresponding values before the plasma process is performed. Table 1 shows the surface roughness and the diameter of the top surfaces of the cylindrical portions 91b in each sample. Here, in Table 1, differences in surface roughness before and after performing the plasma process and differences in a diameter before and after performing the plasma process are indicated.

In the experimental example 1, both the surface roughness and the diameter of the cylindrical portions 91b are found to be substantially same as those of the reference example 1. Meanwhile, in the comparative example 1, the surface roughness is found to be increased whereas the diameter is decreased, as compared to the experimental example 1. In view of this, it is provided that, in the plasma cleaning process without using a dummy wafer, it is possible to reduce damage on the surface of the electrostatic chuck 33b by applying the DC voltage.

(Experiment 2: Erosion Test by Plasma Sputtering Action)

In order to quantify a variation in the intensity of a sputtering action by plasma depending on a magnitude of an applied DC voltage, a plasma process is performed on a polysilicon chip mounted in a clean vacuum chamber. Then, thickness and surface roughness (Ra) of the polysilicon chip are measured. Furthermore, a surface of the polysilicon chip is also observed by a SEM. Processing conditions are as follows.

Pressure within vacuum chamber: about 53.3 Pa (about 400 mTorr)

First high frequency power: about 800 W

Kind and flow rate of cleaning gas: O₂ gas, about 700 sccm

Plasma processing time: about 5 hours

Applied DC voltage: about 0 V (comparative example 2), about −300 V (experimental example 2)

The magnitude of the DC voltage as one parameter of the present experiment is set to be about 0 V and about −300 V. A sample when the DC voltage is set to about 0 V is referred to as a comparative example 2 and a sample when the DC voltage is set to about −300 V is referred to as an experimental example 2. A sample before performing the plasma process is referred to as a reference example 2. Experiment result is provided in FIG. 8.

As for the comparative example 2, surface roughness of a polysilicon chip is found to be decreased and the surface of the polysilicon chip observed through SEM is found to be smooth, as compared to the reference example 2. Furthermore, thickness of the polysilicon chip is found to be reduced. Such a decrease of the surface roughness and the thickness of the chip and the smoothened surface of the chip are deemed to be caused by a sputtering action by the plasma. In the experimental example 2, thickness and surface roughness of a polysilicon chip and a surface state thereof observed through SEM are all found to be substantially the same as those of the reference example 2. That is, it is shown that the sputtering action by plasma can be reduced by applying the DC voltage to the plasma.

(Experiment 3: Erosion Test by Plasma Sputtering Action)

In order to quantify a variation in the intensity (hereinafter, referred to as a sputtering force) of a sputtering action by plasma depending on whether a DC voltage is applied or not, a plasma process is performed on a wafer having a thermal oxide (Th—SiO₂) film formed thereon, and sputtering rates at multiple positions of the wafer in a radial direction of the wafer are measured. Processing conditions are as follows.

Pressure within vacuum chamber: about 53.3 Pa (about 400 mTorr)

First high frequency power: about 800 W

Kind and flow rate of cleaning gas: argon (Ar) gas, about 700 sccm

Plasma processing time: about 1 minute

Applied DC voltage: about 0 V (comparative example 3), about −300 V (experimental example 3)

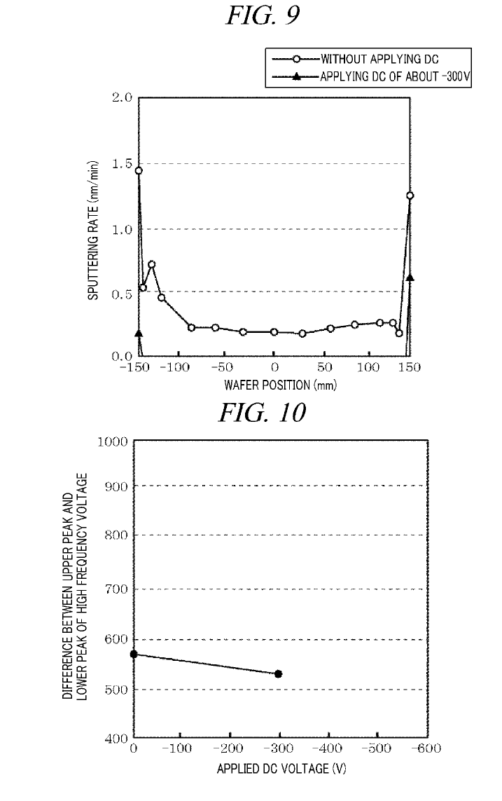

A sample in case of applying a DC voltage of about −300 V is referred to as an experimental example 3, and a sample in case of not applying a DC voltage is referred to as a comparative example 3. Experiment result is provided in FIG. 9.

In the comparative example 3, sputtering rates are found to be substantially uniform, ranging from about 0.2 nm to about 0.3 nm, over the entire surface of the wafer from a central portion to a periphery portion thereof. Meanwhile, in the experimental example 3, a wafer is not sputtered at any position. From this result, it is shown that the sputtering action by the plasma can be reduced by applying the DC voltage to the plasma.

(Experiment 4: Relationship Between Applied DC Voltage and Vₚₚ)

As stated above, a sputtering force of plasma is deeply related with a maximum value Vₘ of ion energy of the plasma. Furthermore, the maximum value Vₘ of the ion energy is deeply related with a Vₚₚ (difference between an upper peak and a lower peak) of a high frequency voltage Vₐₚ. Accordingly, by measuring the Vₚₚ, the sputtering force of the plasma can be estimated. In experiment 4, a Vₚₚ is measured while varying the magnitude of an applied DC voltage and a certain magnitude of the applied DC voltage capable of suppressing the sputtering force is investigated. Processing conditions are follows.

Pressure within vacuum chamber: about 53.3 Pa (about 400 mTorr)

First high frequency power: about 800 W

Kind and flow rate of cleaning gas: O₂ gas, about 700 sccm

Applied DC voltage: about 0 V, about −300 V

Experiment result is provided in FIG. 10.

By applying a DC voltage of about −300 V, a Vₚₚ is found to be decreased. From this result, it is shown that a sputtering action by plasma can be reduced by applying the DC voltage.

(Experiment 5: Relationship Between Applied DC Voltage and Ion Energy)

A maximum value Vₘ of ion energy is deeply related with a plasma potential Vₚ. Accordingly, by measuring the plasma potential Vₚ, a sputtering force of plasma can be estimated. In experiment 5, a plasma potential Vₚ is measured while varying a magnitude of an applied DC voltage, and a certain magnitude of the applied DC voltage capable of suppressing the sputtering force is investigated. Processing conditions are as follows.

Pressure within vacuum chamber: about 53.3 Pa (about 400 mTorr)

First high frequency power: about 800 W

Kind of ions in cleaning gas: Ar⁺ ions, CF⁺ ions, CF₃⁺ ions

Applied DC voltage: about 0 V, about −300 V

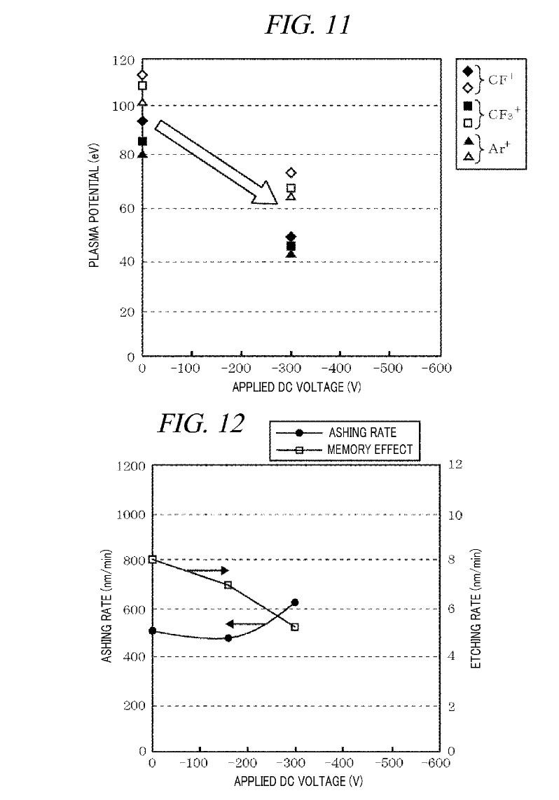

Experiment result is provided in FIG. 11.

For all kinds of gases, it is found that a plasma potential Vₚ is decreased as a result of applying a DC voltage of about −300 V. From this result, it is shown that ion energy can be reduced by applying a DC voltage in various kinds of plasma gases.

(Experiment 6: Relationship Between Applied DC Voltage, Ashing Rate and Memory Effect)

An ashing rate and a memory effect in a plasma process are measured while varying the magnitude of an applied DC voltage. The memory effect is investigated by performing a plasma process on a wafer after making a large amount of previously generated CF-based deposits adhere to the inside of the vacuum chamber. Here, the amount of the CF-based deposits is set to be large enough so as not to be generated by a typical etching process. Both the ashing rate and the memory effect are measured at a periphery portion of the wafer. Processing conditions are as follows.

Pressure within vacuum chamber: about 53.3 Pa (about 400 mTorr)

First high frequency power: about 800 W

Kind and flow rate of cleaning gas: O₂ gas, about 700 sccm

Plasma processing time: about 1 minute

Applied DC voltage: about 0 V, about −150 V, about −300 V

Experiment result is shown in FIG. 12.

In a range of an applied DC voltage from about 0 V to about −150 V, a variation in an ashing rate is found to be small. However, the ashing rate is found to be increased at the voltage of about −300 V. Meanwhile, the memory effect is continuously decreased in the voltage range from about 0 V to about −300 V. From this result, it is shown that, by applying the DC voltage, a cleaning effect within the vacuum chamber can be ameliorated and the memory effect can be reduced.

| | |
|---|---|
| Center | Periphery |

| | ΔRa | Δ(diameter) | ΔRa | Δ(diameter) |
|---|---|---|---|---|
| | (μm) | (μm) | (μm) | (μm) |
| Experimental | 0.02 | ±0 | 0.07 | ±0 |
| example 1 | | | | |
| (Applying | | | | |
| DC) | | | | |
| Comparative | 0.06 | −0.41 | 0.12 | −0.41 |
| example 1 | | | | |
| (Without | | | | |
| applying DC) | | | | |

What is claimed is:

1. A parallel plate type plasma processing apparatus for mounting a substrate on a mounting table serving as a first electrode in a vacuum chamber; generating plasma of a processing gas by applying a high frequency power between the first electrode and a second electrode; and performing a plasma process on the substrate by the plasma, the apparatus comprising:
a DC voltage application electrode which is provided in a region exposed to the plasma;
a DC power supply configured to apply a DC voltage to the DC voltage application electrode;
a cleaning gas supply unit configured to supply a cleaning gas for cleaning an inside of the vacuum chamber; and
a controller configured to output a control signal so as to cause the plasma processing apparatus to perform a series of processes of supplying the cleaning gas into the vacuum chamber without mounting a substrate on the mounting table; exciting the cleaning gas into plasma by applying a high frequency power between the first electrode and the second electrode; and applying a DC voltage to the DC voltage application electrode while exiting the cleaning gas into the plasma.

2. The plasma processing apparatus of claim 1,
wherein the plasma process is an etching process for etching the substrate by using a CF-based gas, and the cleaning gas is an oxygen gas.

3. The plasma processing apparatus of claim 2,
wherein the DC voltage applied to the DC voltage application electrode ranges from about −200 V to about −320 V.

4. A plasma processing method comprising:
mounting a substrate on a mounting table serving as a first electrode in a vacuum chamber, generating plasma of a processing gas by applying a high frequency power between the first electrode and a second electrode, and performing a plasma process on the substrate by the plasma;
supplying a cleaning gas into the vacuum chamber without mounting a substrate on the mounting table, and exciting the cleaning gas into plasma by applying a high frequency power between the first electrode and the second electrode; and
applying, while exciting the cleaning gas into the plasma, a DC voltage to a DC voltage application electrode provided in a region exposed to the plasma.
